(19) United States
(12) Patent Application Publication
(10) Pub. No.: US 2025/0054421 A1
(43) Pub. Date: Feb. 13, 2025

(54) TRANSPARENT DISPLAY DEVICE

(71) Applicant: LG ELECTRONICS INC., Seoul (KR)

(72) Inventor: Minhee SHIM, Seoul (KR)

(73) Assignee: LG ELECTRONICS INC., Seoul (KR)

(21) Appl. No.: 18/723,111

(22) PCT Filed: Jan. 3, 2022
(86) PCT No.: PCT/KR2022/000021

§ 371 Date: Jun. 21, 2024

(51) Int. Cl. G09F 9/33; F21L 4/08; G09F 19/22; H01G 9/20

(52) U.S. Cl. CPC G09F 9/33; F21L 4/08; G09F 19/227; H01G 9/20

(57) ABSTRACT

A transparent display device comprises: a first base comprising a light-transmissive material; a plurality of light sources disposed on the first base; a display PCB positioned at the end of the first base; a transparent electrode connecting the light sources and the display PCB to each other; a second base covering the light sources; a photoactive layer formed in either the first base or the second base to convert sunlight into electrical energy; and a third base covering the photoactive layer. The transparent display device can self-produce and self-supply power and thus is easy to install.

### TECHNICAL FIELD

The present disclosure relates to a transparent display device capable of operating through self-power generation.

### BACKGROUND ART

There are many different types of display modules that implement images. For example, there are various display modules such as a liquid crystal display panel (LCD), a light emitting diode display panel (LED), a plasma display panel (PDP), and an organic light emitting diode display panel (OLED).

Also, film-type display modules that implement images are known. In particular, with the spread of the OLED, a transparent and flexible film-type display panel, lighter and thinner display devices can be realized, and displays can be installed in various places with transparency controlled.

In particular, recently, display devices that output images using transparent and flexible display modules attached to glass such as windows have been used for outdoor advertisement.

In particular, ultra-small LEDs, such as micro-LEDs, are not visible to the naked eye due to their small size. Thus, a transparent display device can be realized by leaving the area around the micro-LEDs transparent while each micro-LED implements a pixel.

However, unlike mountable display devices, these installable display devices require wiring to supply power and must be installed on-site by installers.

### DISCLOSURE

### Technical Problem

An object of the present disclosure devised to solve the above-described problems is to provide a transparent display device capable of self-supplying power for outputting images by having a transparent solar panel on the front.

### Technical Solution

In one aspect of the present disclosure, a transparent display device may include a first base comprising a light-transmissive material, a plurality of light sources disposed on the first base, a display PCB disposed at an end of the first base, a transparent electrode connecting the light sources and the display PCB, a second base covering the light sources, a photoactive layer formed on one side of the first base or the second base to convert sunlight into electrical energy, and a third base arranged to cover the photoactive layer.

The transparent display device may further include a battery configured to store the electrical energy generated by the photoactive layer, wherein the battery may be disposed at the end of the first base.

The transparent display device may further include a transparent adhesive layer laminated to the third base and adhered to a window, wherein the display PCB and the battery may be disposed on a bezel of the window.

The display PCB may be powered by the battery to control the light sources.

The transparent display device may further include a system controller configured to provide an image signal to the display PCB, wherein the system controller may be driven by power supplied from the battery.

The light sources may be arranged in a grid.

The photoactive layer may include dye molecules configured to generate electrons upon receiving solar energy, nanoporous titanium oxide particles having absorbed the dye molecules, and an electrolyte.

### Advantageous Effects

According to an embodiment of the present disclosure, a transparent display device may self-generate and self-supply power, thereby eliminating the need for wiring for power supply and providing the convenience of simple installation with fewer restrictions on the installation site.

Furthermore, the transparent base located on one side of the transparent display device may be shared with a solar panel. Therefore, the present disclosure may reduce manufacturing costs and reduce thickness.

Effects obtainable from the present disclosure are not limited by the above mentioned effects, and other unmentioned effects can be clearly understood from the above description by those having ordinary skill in the technical field to which the present disclosure pertains.

### DESCRIPTION OF DRAWINGS

FIG. 1 is a view illustrating an example installation of a transparent display device installed on a window according to one embodiment of the present disclosure.

FIG. 2 is a cross-sectional view illustrating a conventional transparent display device.

FIG. 3 is a cross-sectional view illustrating a transparent display device according to the present disclosure.

### BEST MODE

Description will now be given in detail according to exemplary embodiments disclosed herein, with reference to the accompanying drawings. For the sake of brief description with reference to the drawings, the same or equivalent components may be provided with the same reference numbers, and description thereof will not be repeated.

In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

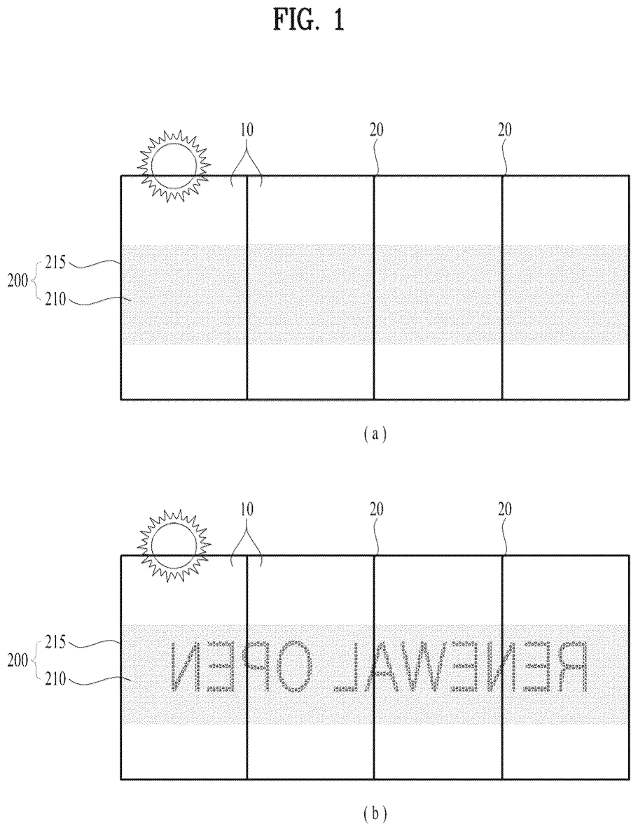

FIG. 1 is a view illustrating an example installation of a transparent display device 200 installed on a window 10 according to one embodiment of the present disclosure. This is a view taken from the inside of the window 10, wherein (a) shows the display device 200 in an off state, and (b) shows the display device 200 in an on state.

The transparent display device 200 of the present disclosure may be installed on the window 10 or the like, and a display film 210 installed on the window 10 is transparent to allow one to see the outside from the inside or to see the inside from the outside.

As the transparent display film 210 increases in size, the number of signal wires increases. Therefore, the transparent display film 210 is modularized and manufactured in a predetermined size, and a plurality of transparent display films 210 may be arranged in a grid on the window 10 to form the transparent display device 200 with a large screen.

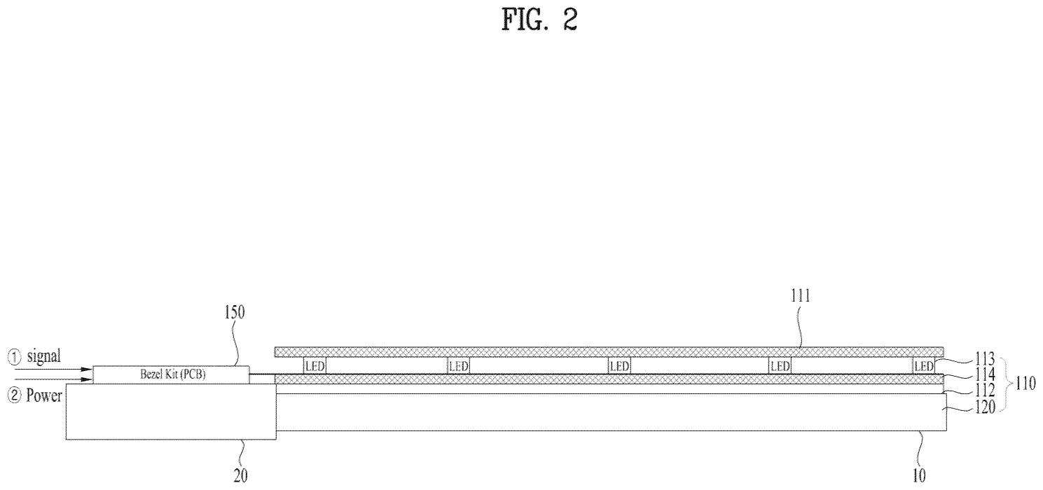

FIG. 2 is a view illustrating one example of a conventional transparent display device 100. The conventional transparent display device 100 may include a plurality of LEDs arranged at predetermined intervals as light sources 113 on a transparent base 111, and a display PCB 150 arranged at an end of the base 111 to control the light sources 113. By disposing the display PCB 150 on a bezel 20, the opaque display PCB may overlap the bezel 20 and be installed so as not to be noticed by the user.

The transparent display device may be attached to the transparent window 10 using an adhesive layer 120. The adhesive layer 120 may be formed of a transparent material, such as an optical clear adhesive (OCA), to allow light from the light sources 113 to pass therethrough.

The transparent display device 200 may be installed on the inside of the window 10 facing an indoor or outdoor area. Other non-transparent components (e.g., the display PCB, the communication part, the system controller and the power supply for controlling a plurality of display films 210) should be installed in a separate place.

Wiring is required from the system controller and power supply to the display films 210 attached to the window. In particular, the installation location is limited for external power supply, and the wiring is long in places without power.

To address the aforementioned issues, a self-powered transparent display device 200 is needed, and the present disclosure may employ a solar panel 230 overlapping the display film 210.

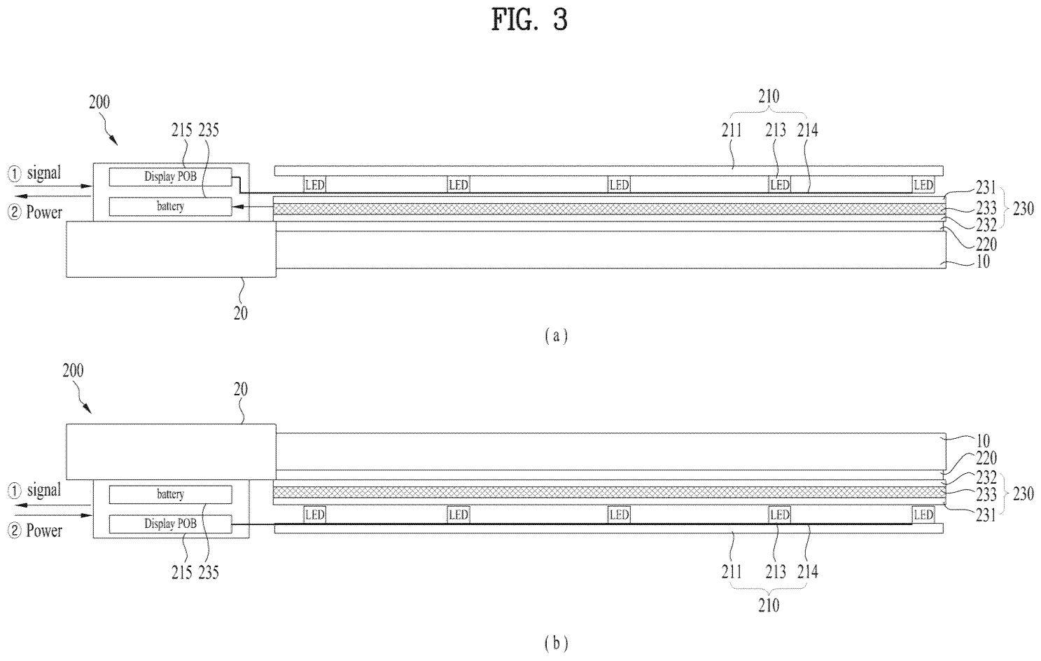

FIG. 3 is a cross-sectional view illustrating the transparent display device 200 of the present disclosure.

The display film 210 may have a plurality of LEDs disposed at predetermined intervals as light sources 213 on a transparent base 211, and a display PCB 215 provided at an end of the base 211 and disposed on a bezel. A transparent electrode 214 connecting the light sources 213 and the display PCB 215 may be formed on the base 111.

A surface of the transparent display device 200 on which images are output may be positioned facing the outside of the building such that the images can be viewed from the opposite side of the window 10.

Since the solar panel 230 requires sunlight to generate electricity, it should be located between the window 10 and the transparent display film 210, as shown in FIG. 3, to increase its efficiency.

Thus, the transparent solar panel 230 may be used to allow the images output from the display film 210 to be transmitted through the solar panel 230.

The solar panels 230 may be broadly divided into a silicon semiconductor type, a compound semiconductor type, and a dye-sensitized type.

The silicon semiconductor type is made by bonding p-type semiconductors and n-type semiconductors using a silicon wafer and placing electrodes on the front and back surfaces. When the silicon semiconductor type receives sunlight, pairs of electrons and holes are generated, and the electrons and holes flow in opposite directions under the influence of the electric field present at the p-n junction, and current flows by connecting the electrodes located on the front and back surfaces.

However, the silicon wafers used for the silicon type solar panels do not allow light to be transmitted therethrough. Instead, the silicon is densely drilled with fine holes on the order of tens of micrometers to implement a solar panel that allows light to be transmitted therethrough. Since objects on the other side can be recognized through the microscopic holes, the panel may be perceived as transparent.

The microscopic holes may increase the flexibility of the solar panel, enabling the implementation of a bendable solar panel. The transparent display film 210 is also bendable when molded on the film-like bendable transparent base 211, and thus may be installed on a curved window 10.

The compound semiconductor solar panel is similar in driving principle to the silicon semiconductor solar panel, but the material used is a compound rather than silicon. Examples of the compounds include copper indium selenium (CIS)-based, copper indium gallium selenium (CIGS)-based, and cadmium telluride (CdTe)-based materials.

The dye-sensitized type solar panel (dye-sensitized solar cell (DSSC)) generates electricity when the dye, like chlorophyll in plants, moves electrons in the presence of light. The dye-sensitized type solar panel is composed of a redox electrolyte, and the dye molecules chemically adsorbed on the surface of the panel may generate electricity by releasing electrons in the presence of sunlight.

The dye-sensitized type solar panels are less efficient than the silicon type solar panels, and therefore the commercialization rate of dye-sensitized type solar panels is still low.

However, the dye-sensitized type solar panels are easier to make than the silicon type solar panels, and may thus require lower manufacturing costs. Further, they have higher stability, and may thus be used for a longer period of time.

They may be implemented with transparency because a transparent base is available instead of opaque silicon. Furthermore, the DSSCs can generate electricity even on cloudy days when direct sunlight is weak, and may thus be used indoors to generate electricity.

As such, the transparent solar panel 230 may be implemented using a dye-sensitized type solar panel or a silicon-type solar panel having microscopic holes. However, the silicon-type solar panel having microscopic holes has a problem that the visibility of the image output from the transparent display decreases if the light sources 213 and the microscopic holes do not overlap when the solar panel is arranged to overlap the transparent display film 210. Thus, the following description will be based on the dye-sensitized type solar panel 230.

For the dye-sensitized type solar panel, a photoactive layer 233 may be implemented using nano-sized oxide (titanium oxide, TiO₂) particles with dye adsorbed on them and an electrolyte. The solar panel 230 may be manufactured by interposing the photoactive layer 233 between a pair of transparent bases 231 and 232 on which transparent electrodes are formed.

Since the solar panel 230 and the transparent display film 210 both require transparent bases 211, 231, and 232, the solar panel 230 may be implemented by omitting the transparent base abutting the transparent display film 210 and using the transparent base 231 of the display film 210.

The power generated by the solar panel 230 may be used to drive the transparent display film 210. A battery 235 that stores power generated by the solar panel 230 may be disposed with a system controller, and may be disposed on the bezel 20 along with the display PCB 215 as shown in FIG. 3.

The power generated by the solar panel 230 may not only drive the light sources 213 of the transparent display film 210, but may also power the system controller.

According to embodiments of the present disclosure, electricity may be produced and supplied independently, and therefore wiring for power supply may be omitted.

Therefore, the installation is simple and there are fewer restrictions on the installation site.

Furthermore, according to the present disclosure, the transparent base located on one side of the transparent display device 200 may be shared with the solar panel 230, thereby reducing manufacturing costs and reducing thickness.

The above detailed description should not be construed as being limitative in all terms, but should be considered as being illustrative. The scope of the present invention should be determined by reasonable analysis of the accompanying claims, and all changes in the equivalent range of the present invention are included in the scope of the present invention.

1. A transparent display device comprising:
a first base and a second base each comprising a light-transmissive material;
a plurality of light sources disposed between the first base and the second base;
a display PCB disposed at an end of the first base or the second base;
a transparent electrode connecting the light sources and the display PCB;
a photoactive layer formed on the second base to convert sunlight into electrical energy; and
a third base arranged to cover the photoactive layer.

2. The transparent display device of claim 1, further comprising:
a battery configured to store the electrical energy generated by the photoactive layer,
wherein the battery is disposed at the end of the first base.

3. The transparent display device of claim 2, further comprising:
a transparent adhesive layer laminated to the third base and adhered to a window,
wherein the display PCB and the battery are disposed on a bezel of the window.

4. The transparent display device of claim 2, wherein the display PCB is powered by the battery to control the light sources.

5. The transparent display device of claim 2, further comprising:
a system controller configured to provide an image signal to the display PCB,
wherein the system controller is driven by power supplied from the battery.

6. The transparent display device of claim 1, wherein the light sources are arranged in a grid.

7. The transparent display device of claim 1, wherein the photoactive layer comprises:
dye molecules configured to generate electrons upon receiving solar energy:
nanoporous titanium oxide particles having absorbed the dye molecules; and
an electrolyte.
